(19) United States
(12) Patent Application Publication
(10) Pub. No.: US 2008/0069574 A1
(43) Pub. Date: Mar. 20, 2008

(54) Optical communication module and electronic equipment

(75) Inventors: Tomohiro Yamazaki, Kyoto (JP); Jun Ichihara, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 11/785,920

(22) Filed: Apr. 20, 2007

(30) Foreign Application Priority Data
Apr. 24, 2006 (JP) 2006-119664

(51) Int. Cl. H01L 31/0203

(52) U.S. Cl. 398/212; 385/93

(57) ABSTRACT

An inventive optical communication module includes a substrate, a light receiving element disposed on one surface of the substrate for receiving light emitted from a transmission-side optical communication module, a block-shaped resin package which seals the one surface of the substrate and the light receiving element, and a lens disposed on a light incidence surface of the resin package opposite from a surface of the resin package contacting the substrate for converging the light emitted from the transmission-side optical communication module on the light receiving element. The resin package has a groove provided in a side face thereof intersecting the light incidence surface thereof.

### BACKGROUND OF THE INVENTION

1. Field of the Invention

The present invention relates to an optical communication module.

2. Description of Related Art

In recent years, optical communication (infrared communication) modules have been rapidly prevailing, which are mounted on mobile devices such as mobile phones and PDAs (Personal Digital Assistants) for use as short-distance data communication modules.

FIG. 5 is a schematic diagram showing communications between optical communication modules.

An optical communication module 91 on a transmission side includes a light emitting diode (LED) 92, and a lens 93 which transmits light emitted from the light emitting diode 92. The light from the light emitting diode 92 passes through the lens 93 and travels with its beam diameter steadily increasing (travels radially).

On the other hand, an optical communication module 94 on a reception side is disposed in a light passage area (illumination area) in which the light emitted from the transmission-side optical communication module 91 passes. The reception-side optical communication module 94 includes a photodiode (PD) 95, and a lens 96 which converges the light from the transmission-side optical communication module 91 on the photodiode 95. The diameter of the lens 96 is much smaller than the beam diameter of the light from the optical communication module 91, so that a small fraction of the light from the optical communication module 91 is incident on the photodiode 95.

The optical communication module employing the light emitting diode generally has a data transfer speed of about several Mbps to about several tens Mbps. However, there are limitations in increasing the output and response speed of the light emitting diode, making it difficult to increase the data transfer speed by a factor of several hundreds to several thousands, i.e., to a Gbps level. Therefore, it is proposed to employ, instead of the light emitting diode, a laser diode (LD) which has a higher output and a higher responsiveness than the light emitting diode.

The communicable range of the optical communication module employing the light emitting diode is defined by the relatively large light passage area in which the light travels radially as shown in FIG. 5. Where the laser diode is employed as the light emitting element, however, the communicable range is relatively small because of a high directivity of the laser diode.

### SUMMARY OF THE INVENTION

The inventors of the present invention made an attempt to expand the communicable range by increasing the diameter of the lens for converging the light from the transmission-side optical communication module on the light receiving element (photodiode) to a level greater than the light beam diameter of the laser diode. However, it is found that the increase in the diameter of the lens increases the curvature of the lens and hence increases the focal length of the lens, thereby increasing the size of a resin package in which the light receiving element is sealed. This causes a new problem with difficulty in production of the resin package (particularly, in cutting the resin package).

It is an object of the present invention to provide an optical communication module which permits easy production of a resin package even if having a greater size, and to provide electronic equipment including the optical communication module.

An optical communication module according to the present invention includes a substrate, a light receiving element which receives light emitted from a transmission-side optical communication module, the light receiving element being disposed on one surface of the substrate, a block-shaped resin package which seals the one surface of the substrate and the light receiving element, and a lens which converges the light emitted from the transmission-side optical communication module on the light receiving element, the lens being disposed on a light incidence surface of the resin package opposite from a surface of the resin package contacting the substrate. The resin package has a groove provided in a side face thereof intersecting the light incidence surface thereof.

Electronic equipment according to the present invention includes a reception-side optical communication module which optically communicates with a transmission-side optical communication module provided on other electronic equipment. The reception-side optical communication module includes a substrate, a light receiving element which receives light emitted from the transmission-side optical communication module, the light receiving element being disposed on one surface of the substrate, a block-shaped resin package which seals the one surface of the substrate and the light receiving element, and a lens which converges the light emitted from the transmission-side optical communication module on the light receiving element, the lens being disposed on a light incidence surface of the resin package opposite from a surface of the resin package contacting the substrate. The resin package has a groove provided in a side face thereof intersecting the light incidence surface thereof.

Where the resin package is produced by molding a precursor of the resin package having a groove and then cutting the precursor together with the substrate along a dicing plane which coincides with the side face of the package, the area of contact between a cutting blade and the precursor of the resin package is reduced, thereby reducing a resistance received from the precursor by the cutting blade. Therefore, the resin package can be easily produced even if having a greater size. Further, the wear of the cutting blade occurring when the resin package is cut is reduced.

The side face of the package is preferably flush with a side face of the substrate perpendicular to the one surface of the substrate, and the groove preferably extends over from the light incidence surface to the one surface of the substrate.

With this arrangement, the groove has an elongated shape as extending over from the light incidence surface of the resin package to the one surface of the substrate. Therefore, when the precursor of the resin package is cut along the dicing plane which coincides with the side face of the package, the resistance received from the resin package by the cutting blade is further reduced.

The substrate preferably has an electrode formed on the other surface thereof opposite from the one surface thereof and on the side face thereof flush with the side face of the package for electrical connection between the light receiving element and an external device.

With this arrangement, the electrode is formed on the other surface of the substrate opposite from the resin package. Therefore, the electrical connection between the electrode and an interconnection on the external device can be established by bringing the other surface of the substrate into contact with the external device (e.g., a mounting board). Further, the electrode is also formed on the side face of the substrate flush with the side face of the package. Therefore, the electrical connection between the electrode and the interconnection on the external device can also be established by bringing the side face of the substrate into contact with the external device. In this case, the optical communication module can be stably supported on the external device by the side face of the package in contact with the external device.

The foregoing and other objects, features and effects of the present invention will become more apparent from the following detailed description of the embodiments with reference to the attached drawings.

### BRIEF DESCRIPTION OF THE DRAWINGS

FIG. 1 is a schematic diagram showing communications with an optical communication module according to one embodiment of the present invention;

FIG. 2A is a perspective view of a reception-side optical communication module shown in FIG. 1;

FIG. 2B is a perspective view for explaining a production method for the optical communication module shown in FIG. 2A;

FIG. 3 is a perspective view illustrating another configuration of the optical communication module shown in FIG. 1;

FIG. 4 is a schematic diagram for explaining use of the optical communication module shown in FIG. 1; and

FIG. 5 is a schematic diagram showing communications between conventional optical communication modules.

### DESCRIPTION OF THE PREFERRED EMBODIMENTS

Embodiments of the present invention will hereinafter be described in detail with reference to the attached drawings.

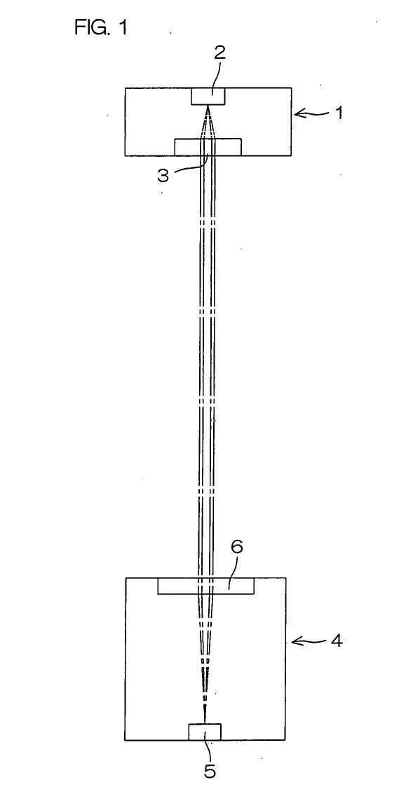

FIG. 1 is a schematic diagram showing communications with an optical communication module according to one embodiment of the present invention.

A transmission-side optical communication module 1 includes a laser diode 2 as a light emitting element, and a collimator lens 3 which converts light (laser beam) emitted from the laser diode 2 into a parallel light beam.

The laser diode 2 emits the light radially. The radial light from the laser diode 2 passes through the collimator lens 3 to be converted into the parallel light beam, which is in turn outputted from the collimator lens 3.

On the other hand, a reception-side optical communication module 4 includes a photodiode 5 as a light receiving element which receives the parallel light beam emitted from the transmission-side optical communication module 1, and a condenser lens 6 of a resin which converges the parallel light beam on the photodiode 5.

The condenser lens 6 has a diameter greater than the light beam diameter of the parallel light beam emitted from the transmission-side optical communication module 1. In this embodiment, for example, the diameter of the parallel light beam is 0.3 mm, and the diameter of the condenser lens 6 is 3 mm. Thus, a communicable range for communication between the optical communication modules 1 and 4 is not dependent upon the light passage area in which the light from the transmission-side optical communication module 1 passes, but dependent upon the diameter of the condenser lens 6 provided in the transmission-side optical communication module 4. Therefore, even if the laser diode 2 having a higher directivity than the light emitting diode is employed as the light emitting element, the communicable range is expanded beyond the light passage area in which the light from the laser diode passes. Thus, the use of the laser diode 2 as the light emitting element permits high speed data transfer while ensuring a proper communicable range.

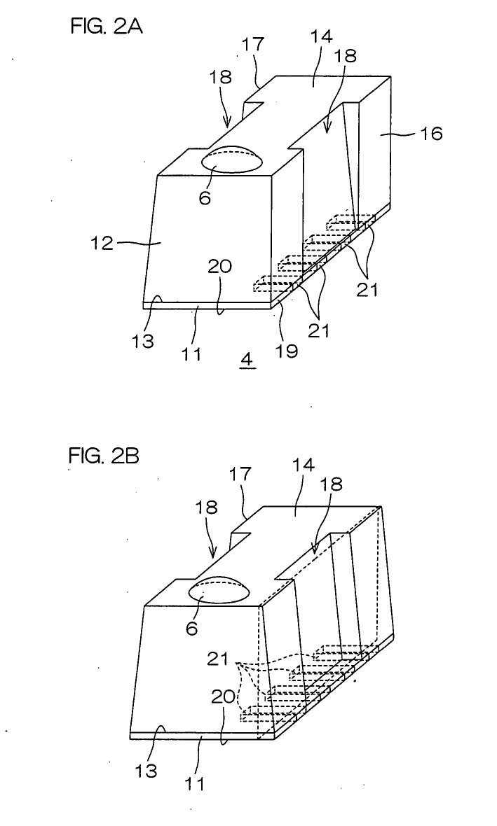

FIG. 2A is a perspective view of the reception-side optical communication module 4. FIG. 2B is a perspective view of the optical communication module 4 in production.

The reception-side optical communication module 4 includes a rectangular planar substrate 11, and a block-shaped resin package 12 provided on one surface of the substrate 11. The photodiode 5 is disposed on the one surface 13 (an upper surface in FIG. 2A) of the substrate 11, and the one surface 13 of the substrate 11 and the photodiode 5 are sealed in the resin package 12. The condenser lens 6 is disposed at a longitudinally offset position on a light incidence surface 14 (an upper surface in FIG. 2A) of the resin package 12 opposite from a surface of the resin package contacting the one surface 13 of the substrate 11.

Grooves 18 each having a rectangular shape as seen perpendicularly to the light incidence surface 14 are respectively provided in opposite side faces 16, 17 extending longitudinally of the resin package 12. The grooves 18 each extend from the light incidence surface 14 to the one surface 13 of the substrate 11 perpendicularly to the light incidence surface 14 (or the one surface 13 of the substrate 11).

The side face 16 of the resin package 12 is perpendicular to the light incidence surface 14 and the one surface 13 of the substrate 11, and flush with a side face 19 of the substrate 11. On the other hand, the side face 17 of the resin package 12 is inclined with a distance from the side face 16 progressively increasing in a direction from the light incidence surface 14 toward the one surface 13 of the substrate 11. That is, longitudinally opposite side faces of the resin package 12 each have a shape such that the light incidence surface 14 has a smaller width than the surface of the resin package contacting the one surface 13 of the substrate 11. The side face 16 of the resin package 12 is perpendicular to the light incidence surface 14 and the surface of the resin package contacting the one surface 13 of the substrate 11, and the side face 17 of the resin package 12 is inclined with respect to the light incidence surface 14 and the surface of the resin package containing the one surface 13 of the substrate 11.

The substrate 11 includes a plurality of electrodes 21 (four electrodes 21 in FIG. 2A) arranged longitudinally thereof in generally equidistantly spaced relation. Each of the electrodes 21 is embedded in grooves each formed in the substrate 11 by cutting away a generally rectangular portion as seen in plan from the side face 19 flush with the side face 16 of the resin package 12, and exposed on the side face 19 of the substrate 11 and on the other surface 20 opposite from the one surface 13. Thus, electrical connection between the electrodes 21 of the reception-side optical communication module 4 and an interconnection on a mounting board as an external device is established by bringing the other surface 20 of the substrate 11 into contact with the mounting board as well as by bringing the side face 19 of the substrate 11 into contact with the mounting board. Where the optical communication module 4 is mounted on the mounting board with the side face 19 of the substrate 11 thereof in contact with the mounting board, the side face 16 of the resin package 12 contacts the mounting board, so that the optical communication module 4 is supported by the side face 16 to be kept in a stable attitude on the mounting board.

The optical communication module 4 is produced in the following manner. First, a photodiode 5 is mounted on one surface 13 of a substrate 11. The photodiode 5 is electrically connected to each electrode 21 provided in the substrate 11 via wires. In turn, the substrate 11 mounted with the photodiode 5 is set in a mold, and a resin material is injected into the mold. Thus, a precursor of the resin package 12 is molded, which has grooves 18 on opposite side faces thereof extending longitudinally thereof as shown in FIG. 2B. The opposite side faces of the precursor of the resin package 12 respectively having the grooves 18 are inclined as diverging in the direction from the light incidence surface 14 toward the one surface 13 of the substrate 11. The inclination provides a draft angle for taking out the precursor of the resin package 12 from the mold. Further, a condenser lens 6 of the resin material is integrally formed on the light incidence surface 14 of the resin package 12 during the molding of the resin package 12. Thereafter, the precursor of the resin package 12 and the substrate 11 are cut along a dicing plane indicated by a broken line in FIG. 2B, whereby the optical communication module 4 shown in FIG. 2A is provided.

Since the laser diode 2 is employed as the light emitting element as described above, high speed data transfer between the transmission-side optical communication module 1 and the reception-side optical communication module 4 can be achieved. More specifically, the optical communication module employing the light emitting diode has a data transfer speed of about several Mbps to about several tens Mbps, but the data transfer speed is increased by a factor of several hundreds to several thousands, i.e., to a Gbps level, according to this embodiment.

Further, the condenser lens 6 has a diameter greater than the light beam diameter of the parallel light beam emitted from the transmission-side optical communication module 1. Thus, the communicable range for communication between the optical communication modules 1 and 4 is not dependent upon the light passage area in which the light from the optical communication module 1, but dependent upon the diameter of the condenser lens 6. Therefore, even if the laser diode 2 having a higher directivity than the light emitting diode is employed as the light emitting element, the communicable range is expanded beyond the light passage area of the laser diode 2. Therefore, the use of the laser diode 2 as the light emitting element permits high speed data transfer while ensuring a proper communicable range.

Further, the grooves 18 are already provided in the precursor of the resin package 12 after the molding. Therefore, when the substrate 11 and the precursor of the resin package 12 are cut, the area of contact between a cutting blade and the precursor of the resin package 12 can be reduced, thereby reducing a resistance received from the precursor of the resin package 12 by the cutting blade. Therefore, the resin package 12 can be easily produced even if having a greater size. Further, the wear of the cutting blade occurring when the resin package 12 is cut can be reduced.

In addition, the grooves 18 each have an elongated shape as extending over from the light incidence surface 14 to the one surface 13 of the substrate 11 in this embodiment. Therefore, when the precursor of the resin package 12 is cut, the resistance received from the precursor of the resin package 12 by the cutting blade can be further reduced.

Since the electrodes 21 are formed on the other surface 20 of the substrate 11, the electrical connection between the electrodes 21 and the interconnection on the mounting board can be established by bringing the other surface 20 of the substrate 11 into contact with the mounting board. Further, the electrodes 21 are formed on the side face 19 of the substrate which is flush with the side face 16 of the resin package 12. Therefore, the electrical connection between the electrodes 21 and the interconnection on the mounting board can be established by bringing the side face 19 into contact with the mounting board. In addition, the side face 16 of the resin package 12 is flush with the side face 19 of the substrate 11. Therefore, the optical communication module 4 can be stably supported on the mounting board by the side face 16 of the resin package 12 in contact with the mounting board.

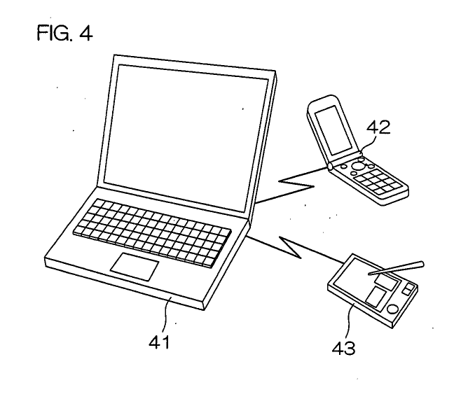

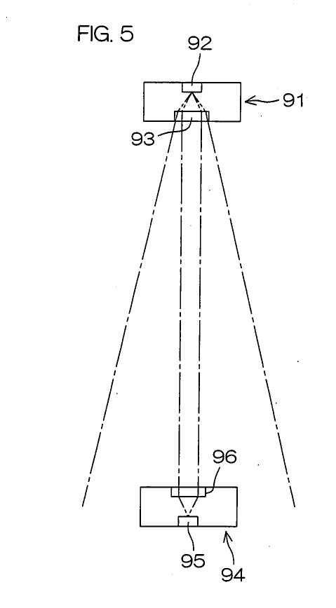

FIG. 4 is a schematic diagram for explaining the use of the optical communication modules 1, 4.

The optical communication modules 1, 4 are each mounted on a mobile device (electronic equipment) such as a laptop PC (personal computer) 41, a mobile phone 42 or a PDA 43, and used for data communications therebetween. Where the transmission-side optical communication module 1 is provided in a mobile phone 42, for example, address data or the like is transmitted from the mobile phone 42 to a laptop PC 41 including the reception-side optical communication module 4. Further, where the transmission-side optical communication module 1 is provided in a PDA 43, schedule data or the like is transmitted from the PDA 43 to the laptop computer 41 including the reception-side optical communication module 4.

The aforementioned arrangement is adapted for unidirectional communications from the transmission-side optical communication module 1 to the reception-side optical communication module 4. For bidirectional communications between the optical communication modules 1 and 4, elements equivalent to the photodiode 5 and the condenser lens 6 may be provided in the transmission-side optical communication module 1, and elements equivalent to the laser diode 2 and the collimator lens 3 may be provided in the reception-side optical communication module 4. In this case, bidirectional data communications can be achieved, for example, between the laptop PC 41, the mobile phone 42 and the PDA 43.

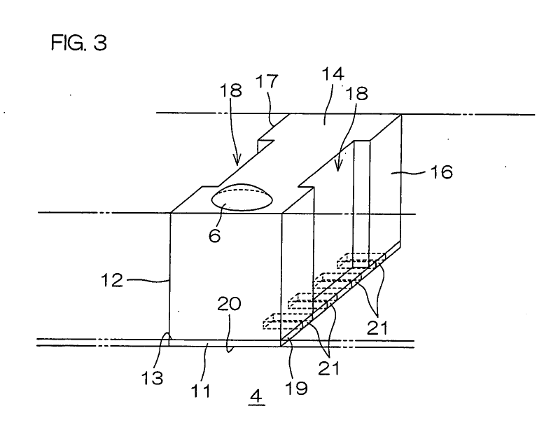

In the embodiment described above, only the side face 16 of the resin package 12 is perpendicular to the light incidence surface 14 and the one surface 13 of the substrate 11, and the opposite side face 17 is inclined with the distance thereof from the side face 16 progressively increasing in the direction from the light incidence surface 14 toward the one surface 13 of the substrate 11. However, both the side faces 16, 17 may be perpendicular to the light incidence surface 14 and the one surface 13 of the substrate 11 as shown in FIG. 3. The optical communication module 4 having such a construction is produced, for example, in the following manner. A plurality of modules with a plurality of substrates 11 connected to one another are set in a mold, and a resin material is injected into the mold, whereby a plurality of resin packages 12 (each having grooves 18) are integrally molded on the respective modules as shown by phantom lines in FIG. 3. Then, the molded product is taken out of the mold, and cut at intervals properly spaced along the continuous arrangement of the substrates 11.

In the embodiment described above, the diameter of the condenser lens 6 is 3 mm, but is merely required to be greater than the light beam diameter of the parallel light beam from the transmission-side optical communication module 1. Where the light beam diameter of the parallel light beam is 0.01 to 0.1 mm, the diameter of the condenser lens 6 is preferably not smaller than 2 mm. Where data communications are to be achieved between one of the optical communication modules provided on a ceiling of an office and the other optical communication module provided in a personal computer or the like, for example, the diameter of the condenser lens 6 is preferably about 10 cm.

While the present invention has been described in detail by way of the embodiments thereof, it should be understood that these embodiments are merely illustrative of the technical principles of the present invention but not limitative of the invention. The spirit and scope of the present invention are to be limited only by the appended claims.

This application corresponds to Japanese Patent Application No. 2006-119664 filed with the Japanese Patent Office on Apr. 24, 2006, the disclosure of which is incorporated herein by reference.

1. An optical communication module comprising:
a substrate;
a light receiving element which receives light emitted from a transmission-side optical communication module, the light receiving element being disposed on one surface of the substrate;
a block-shaped resin package which seals the one surface of the substrate and the light receiving element; and
a lens which converges the light emitted from the transmission-side optical communication module on the light receiving element, the lens being disposed on a light incidence surface of the resin package opposite from a surface of the resin package contacting the substrate;
wherein the resin package has a groove provided in a side face thereof intersecting the light incidence surface thereof.

2. An optical communication module according to claim 1, wherein
the side face of the package is flush with a side face of the substrate perpendicular to the one surface of the substrate, and
the groove extends over from the light incidence surface to the one surface of the substrate.

3. An optical communication module according to claim 1, wherein the substrate has an electrode formed on the other surface thereof opposite from the one surface thereof and on a side face thereof flush with the side face of the package for electrical connection between the light receiving element and an external device.

4. Electronic equipment comprising a reception-side optical communication module which optically communicates with a transmission-side optical communication module provided in other electronic equipment, wherein the reception-side optical communication module comprises:
a substrate;
a light receiving element which receives light emitted from the transmission-side optical communication module, the light receiving element being disposed on one surface of the substrate;
a block-shaped resin package which seals the one surface of the substrate and the light receiving element; and
a lens which converges the light emitted from the transmission-side optical communication module on the light receiving element, the lens being disposed on a light incidence surface of the resin package opposite from a surface of the resin package contacting the substrate;
the resin package having a groove provided in a side face thereof intersecting the light incidence surface thereof.
